(19) United States
(12) Patent Application Publication
(10) Pub. No.: US 2010/0327973 A1
(43) Pub. Date: Dec. 30, 2010

(54) AMPLIFIER CIRCUIT COMPRISING CHARGE PUMP AND LOW-PASS FILTER

(75) Inventor: Shuichi Takada, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/819,509

(22) Filed: Jun. 21, 2010

(30) Foreign Application Priority Data
Jun. 24, 2009 (JP) 2009-150039

(51) Int. Cl. H03F 3/217

(52) U.S. Cl. 330/251

(57) ABSTRACT

According to one embodiment, an amplifier circuit includes a clock generation circuit, a switching amplifier circuit, and a smoothing circuit. The clock generation circuit generates a pseudo random period pattern signal whose period varies. The switching amplifier circuit samples an input signal based on the pseudo random period pattern signal used as a sampling clock. The smoothing circuit smoothes an output signal of the switching amplifier circuit.

### CROSS-REFERENCE TO RELATED APPLICATION

This application is based upon and claims the benefit of priority from Japanese Patent Application No. 2009-150039, filed Jun. 24, 2009; the entire contents of which are incorporated herein by reference.

### FIELD

Embodiments described herein related generally to an amplifier circuit, for example, an amplifier circuit provided on a large-scale integrated (LSI) circuit and provided a random sampling system.

### BACKGROUND

Conventionally, an amplifier circuit which amplifies a minute signal is required to provide low 1/f noise and low offset characteristic. As one method, a method using a chopper amplifier is frequently used (see e.g., “Circuits and Systems, 2005. ISCAS 2005. IEEE International Symposium on Publication Date: 23-26 May 2005” and Jpn. Pat. Appln. KOKAI Publication No. 2007-208924).

The chopper amplifier is a circuit providing the following functions (1) to (3).

(1) A function of converting (modulating) an infinitesimal signal of DC to several MHz to an AC signal of a high-frequency band in which the performance of an operational amplifier is fully exhibited

(2) A function of converting (demodulating) a modulated AC signal which has been amplified to a low-frequency signal by use of a low-pass filter (LPF) again

(3) A function of separating 1/f noise occurring in the operational amplifier from an amplified signal

However, in the case of the above chopper amplifier, a large-capacitance capacitor is required. The capacitor removes a modulation frequency component (chopper frequency component) of a sampling clock which is superimposed on an output of the chopper amplifier at the chopping.

Further, even if an LPF providing a large-capacitance capacitor is applied, it is difficult to completely remove the chopper frequency component.

For example, in order to remove the chopper frequency component from an amplified signal, it is necessary to further increase the chopper frequency. However, this makes the operation frequency band of the chopper amplifier high. Therefore, the difficulty in designing the amplifier is enhanced.

That is, an increase in the chopper frequency causes noise of a high-frequency component (high-frequency noise) to be amplified.

In other words, it is necessary to take a measure against noise in the conventional chopper amplifier in order to prevent the chopper frequency from leaking to a power source line or silicon substrate. when an LPF provided a large-capacitance capacitor is applied, the frequency band of an input infinitesimal signal is limited in view of the stability of the circuit operation and thus a trade-off relationship occurs between the input frequency band and the chopper frequency component. This causes the difficulty in the circuit design to be raised.

### BRIEF DESCRIPTION OF THE DRAWINGS

FIG. 1 is a circuit block diagram showing an example of the configuration of an amplifier circuit according to a first embodiment;

FIG. 2 is a circuit diagram showing an example of the configuration of a clocked comparator in the amplifier circuit of FIG. 1;

FIG. 3A, and FIG. 3B are configuration diagrams showing an example of a pseudo random bit sequence (PRBS) signal generation circuit in the amplifier circuit of FIG. 1;

FIG. 4 is a waveform diagram showing an example of a PRBS signal generated by the PRBS signal generation circuit of FIG. 3;

FIG. 5A, and FIG. 5B show an output of the amplifier circuit of FIG. 1, FIG. 5A being a waveform diagram of an output signal when the PRBS signal is used as a sampling clock and FIG. 5B being a waveform diagram (the result of frequency analysis) when the conventional single clock is used;

FIG. 6 is a waveform diagram showing the frequency characteristic of 1/f noise generated in the amplifier circuit of FIG. 1;

FIG. 7 is a waveform diagram showing the frequency characteristic of an output signal generated in the amplifier circuit of FIG. 1;

FIG. 8 is a circuit block diagram showing an example of the configuration of an amplifier circuit according to a second embodiment;

FIG. 9A, and FIG. 9B are configuration diagrams showing an example of the PRBS signal generation circuit in the amplifier circuit of FIG. 1 or FIG. 8; and

FIG. 10 is a waveform diagram showing an example of a PRBS signal generated by the PRBS signal generation circuit of FIG. 9.

### DETAILED DESCRIPTION

Embodiments will be explained in detail with reference to the accompanying drawings.

In general, according to one embodiment, an amplifier circuit includes a clock generation circuit, a switching amplifier circuit, and a smoothing circuit. The clock generation circuit generates a pseudo random period pattern signal whose period varies. The switching amplifier circuit samples an input signal based on the pseudo random period pattern signal used as a sampling clock. The smoothing circuit smoothes an output signal of the switching amplifier circuit.

### First Embodiment

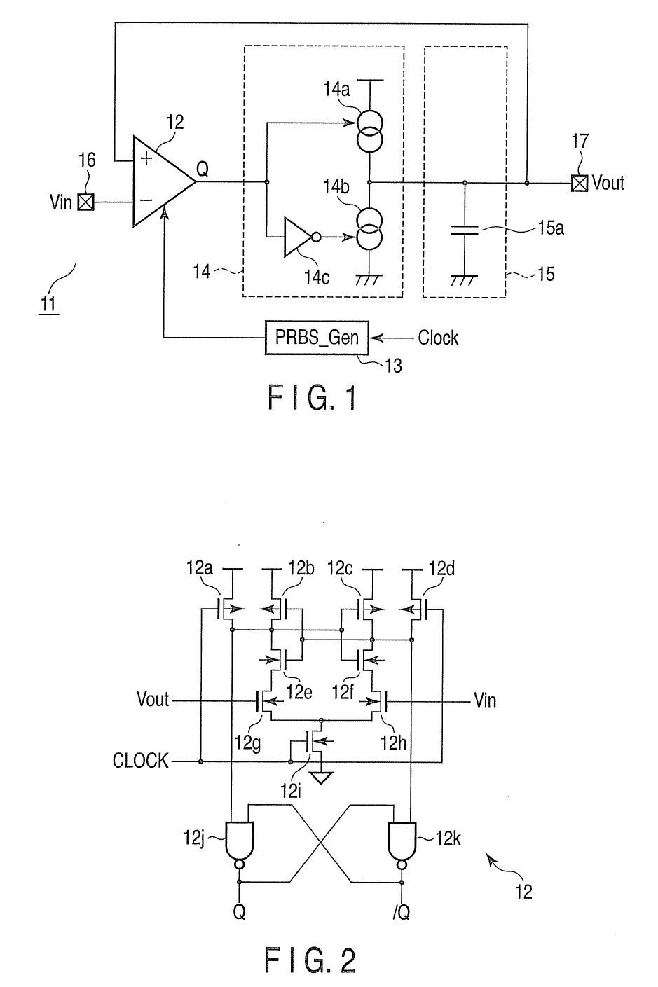

FIG. 1 shows an example of the configuration of an amplifier circuit according to an embodiment. In this embodiment, an amplifier circuit applying a random sampling system which is used as one example is explained.

In this embodiment, it is supposed that the amplifier circuit is provided as a random sampling amplifier circuit suitably used for a reference voltage generation circuit or the like such as a phase-locked loop (PLL) which is severe (comparatively insensitive to input offset) with respect to a modulation frequency component, for example, and is provided in an LSI.

As shown in FIG. 1, the amplifier circuit 11 includes a clocked comparator (switching amplifier) 12, PRBS signal generation circuit (PRBS_Gen) 13, charge pump 14 and low-pass filter (LPF) 15.

An input terminal 16 of signal (for example, an infinitesimal signal of DC to several MHz) Vin is connected to an inverting input terminal (−) of the clocked comparator 12. An output terminal of the low-pass filter 15 is connected to a non-inverting input terminal (+) of the clocked comparator 12.

Further, an output terminal 17 of signal Vout is connected to the output terminal of the low-pass filter 15.

The clocked comparator 12 samples input signal Vin and signal Vout based on the PRBS signal from the PRBS signal generation circuit 13.

The clocked comparator 12 outputs a logical level (output Q) corresponding to a voltage difference between signal Vin and signal Vout at the sampling time to the charge pump 14. The logical level is “H (High)” or “L (Low)”, for example.

The clocked comparator 12 includes p-channel MOS transistors 12a to 12d, n-channel MOS transistors 12e to 12i and NAND circuits 12j, 12k as shown in FIG. 2, for example.

The clocked comparator 12 compares signals Vin and Vout at the timing of the rising edge or falling edge of a CLOCK signal (PRBS signal). Then, the clocked comparator 12 outputs the result (voltage difference between signals Vin and Vout) as output Q,/Q. The clocked comparator 12 is already known.

Each back-to-back inverter is arranged on the load side of a differential input transistor pair. The operation point of the back-to-back inverter varies according to potentials of signals Vin and Vout when the CLOCK signal is input and is transited to the stable point.

For example, the differential input transistor pair includes the n-channel MOS transistors 12g, 12h. Further, the back-to-back inverters respectively include the p-channel MOS transistor 12b and n-channel MOS transistor 12e, and p-channel MOS transistor 12c and n-channel MOS transistor 12f.

An RS flip-flop circuit (RS-FF) including the NAND circuits 12j, 12k. The RS flip-flop circuit latches the voltage difference between signals Vin and Vout as a comparison result.

The clocked comparator 12 is set as a clock domain (a current flows only when the CLOCK signal is input) only at the transition point (at the rise time or fall time of the clock signal). Therefore, the power consumption of the amplifier circuit 11 may be reduced.

The PRBS signal generation circuit 13 generates a pseudo random period pattern signal (PRBS signal) according to a generating polynomial which will be described later based on an input clock signal clock. The pseudo random period pattern signal is a high-frequency clock in which the clock intervals (periods) are different.

The PRBS signal generation circuit 13 generates a PRBS signal to sample signal Vin and Vout. The PRBS signal generation circuit 13 supplies the PRBS signal to the clocked comparator 12.

The charge pump 14 includes constant current sources (or voltage switching circuits) 14a, 14b and inverter circuit 14c.

The charge pump 14 charges or discharges the low-pass filter 15 by using a constant current according to a logical level which is output Q of the clocked comparator 12.

The low-pass filter 15 includes a capacitor 15a. The capacitor 15a is charged or discharged by a constant current from the charge pump 14. Therefore, the voltage level of signal Vout is adjusted so that signal Vout may be set closer to signal Vin.

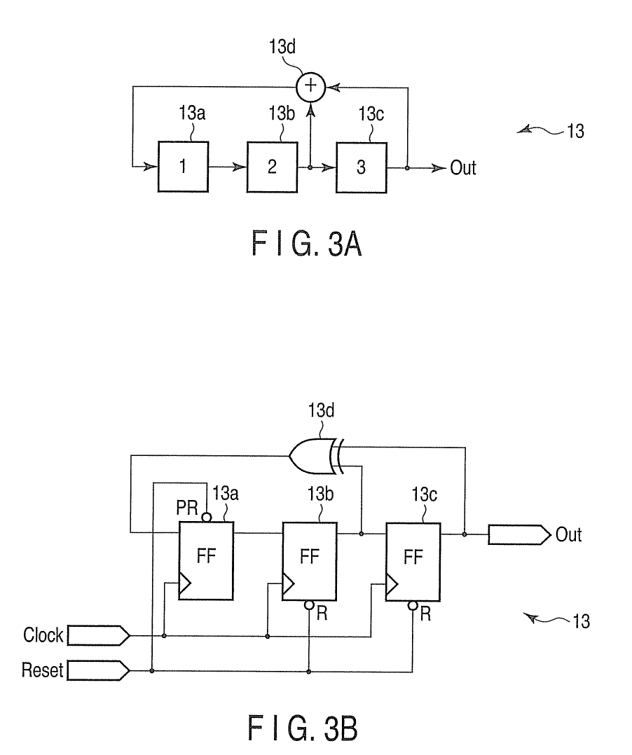

FIG. 3A, and FIG. 3B show an example of the configuration of the PRBS signal generation circuit 13. FIG. 3A is a block diagram in a case where the generating polynomial is set to |1+x²+x³|.

FIG. 3B is a circuit diagram concretely showing the configuration which realizes the generating polynomial of |1+x²+x³|.

For example, in a case where the generating polynomial is set to |1+x²+x³|, the PRBS signal generation circuit 13 includes series-connected three-stage flip-flop circuits (logical circuits) 13a, 13b and 13c and EX-OR circuit (addition circuit) 13d.

The PRBS signal generation circuit 13 adds an output of the second-stage flip-flop circuit 13b and an output (OUT) of the third-stage flip-flop circuit 13c. Then, the EX-OR circuit (addition circuit) 13d performs a logical operation of the result of addition and feeds back the result of operation to the input of the first-stage flip-flop circuit 13a.

Further, output OUT of the third-stage flip-flop circuit 13c is extracted as a PRBS signal.

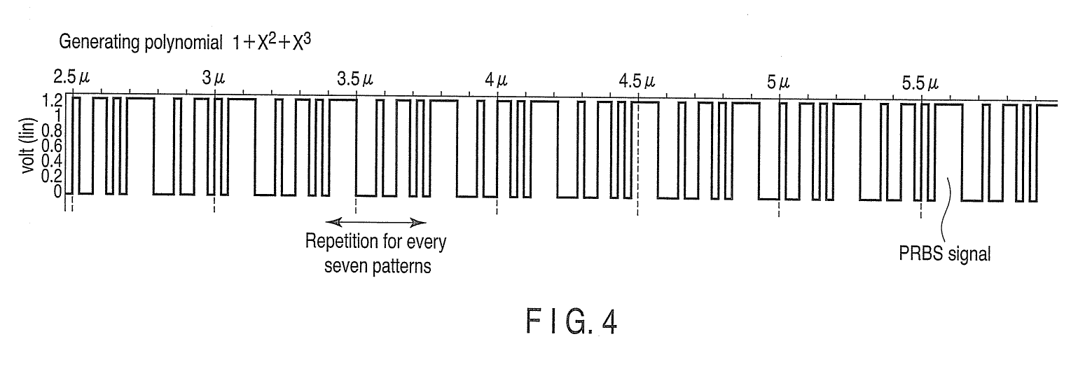

FIG. 4 shows an example of the PRBS signal generated by the PRBS signal generation circuit 13 with the configuration shown in FIG. 3.

That is, if the PRBS signal generation circuit 13 is configured as shown in FIG. 3, a pseudo random period pattern signal whose clock period irregularly varies according to the generating polynomial |1+x²+x³| as shown in FIG. 4, for example, is generated from the PRBS signal generation circuit 13.

In other words, a PRBS signal such as white noise which does not include a so-called specified frequency component is generated from the PRBS signal generation circuit 13.

In the PRBS signal, a signal series of a certain pattern is repeated periodically (in the case of this example, for every seven patterns). Therefore, the modulation frequency component of a sampling clock may be dispersed.

As a result, even if an LPF applying a large-capacitance capacitor is not used as the low-pas filter 15, the modulation frequency (high-frequency noise) component may be easily removed.

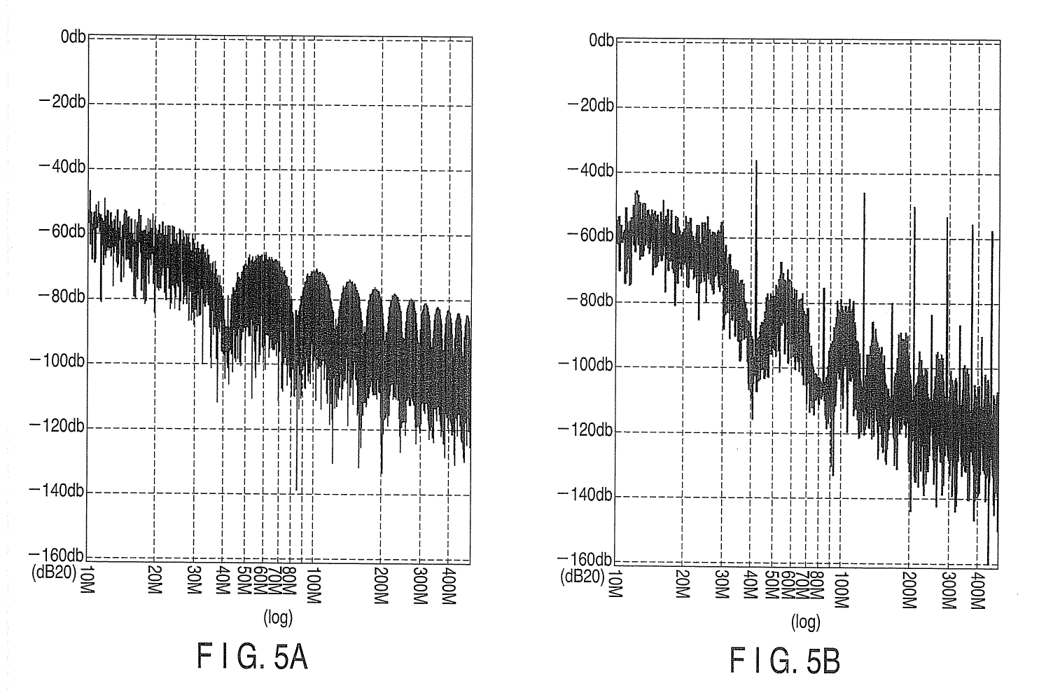

One example of signal Vout in a case where a PRBS signal is used as a sampling clock in the amplifier circuit 11 is shown in FIG. 5A. Further, one example of signal Vout in a case where a conventional high-frequency clock (single clock) of a single frequency is used as a sampling clock is shown in FIG. 5B.

FIG. 5A shows an example of signal Vout in a case where the PRBS signal is used as a sampling clock and FIG. 5B shows an example of signal Vout in a case where the single clock is used as a sampling clock.

As is clearly in FIG. 5B, a large number of high-frequency noise components are present. Therefore, if a single clock is used as a sampling clock, it is necessary to use an LPF applying a large-capacitance capacitor to remove the noise components in signal Vout.

On the other hand, in the case of a PRBS signal, the modulation frequency component of the sampling clock may be dispersed. Therefore, if a PRBS signal is used as a sampling clock, almost no high-frequency noise component which must be removed by use of an LPF applying a large-capacitance capacitor is present in signal Vout.

That is, with the configuration of this embodiment, an abrupt spectrum which appears when the circuit is operated only by applying a single-frequency clock as in the conventional chopper amplifier is suppressed. That is, an abrupt spectrum may be prevented from appearing in the output (signal Vout) of the amplifier circuit 11.

Next, the operation of the amplifier 11 with the above configuration is explained. As shown in FIG. 1, signal Vin input to the input terminal 16 and signal Vout which is an output of the low-pass filter 15 are input to the clocked comparator 12.

The clocked comparator 12 samples input signal Vin and signal Vout based on the PRBS signal from the PRBS signal generation circuit 13.

Then, the charge pump 14 charges or discharges the capacitor 15a of the low-pass filter 15 by use of a constant current according to a logical level of output Q of the clocked comparator 12.

As a result, as indicated by the following equation (1), the voltage level of signal Vout is adjusted. By repeatedly performing the above series of operations, signal Vout appearing on the output terminal 17 is set to the same potential as signal Vin.

$$\begin{matrix}Modulation \\ cos {ω}_{1} t \times cos {ω}_{2} t = \frac{1}{2} \{ cos ( {ω}_{2} + {ω}_{1} ) t + cos ( {ω}_{2} - {ω}_{1} ) t \} \\ Demodulation \\ \{ cos ( {ω}_{2} + {ω}_{1} ) t + cos ( {ω}_{2} - {ω}_{1} ) t \} \times cos {ω}_{2} t \\ = \frac{1}{2} \{ cos ( 2 {ω}_{2} - {ω}_{1} ) t + cos {ω}_{1} t \} + \frac{1}{2} \{ cos ( 2 {ω}_{2} + {ω}_{1} ) t + cos ( - {ω}_{1} ) t \}\end{matrix} \} \\ Source signal \\ \\ Extracted by use of an LPF \qquad ( 1 )$$

where ω1 indicates signal Vin, Vout and ω2 indicates a PRBS signal. Further, in Equation (1), cos ω1t in the first term of the demodulated signal corresponds to a source signal and is extracted by use of an LPF.

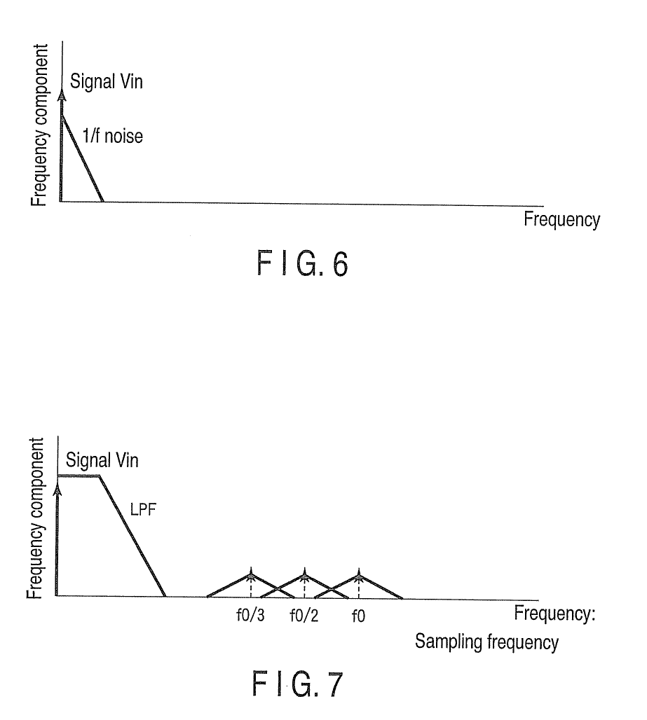

That is, in the clocked comparator 12, signal Vin and signal Vout are sampled by using the PRBS signal. Therefore, as shown in FIG. 6 and FIG. 7, 1/f noise in the clocked comparator 12 is converted into high-frequency side.

Thus, noise is removed when signal Vout which is a low-frequency component is extracted (smoothed) by the charge pump 14 and low-pass filter 15.

As described above, in a case where the circuit is operated at a lower voltage and miniaturized by using a comparator which is capable of sampling an input signal by use of the PRBS signal, an amplifier circuit which may amplify an infinitesimal signal of DC to low frequency may be easily designed.

That is, the amplifier circuit according to this embodiment utilizes a switching amplifier circuit of lower power consumption by using the clock domain instead of the operational amplifier.

Further, the PRBS signal which is a pseudo random period pattern signal corresponding to the generating polynomial and capable of dispersing the modulation frequency components is applied for a sampling clock.

As a result, chopper frequency components leaking into the output signal may be dispersed at a low level. Therefore, noise introduced into a power source or silicon substrate may be reduced. For the above reason, the capacitance of a capacitor applied a low-pass filter used as a countermeasure against 1/f noise may be reduced, the circuit design may be made easy, a reduction in the circuit size may be attained and the operation voltage may be lowered.

In the above embodiment, a case wherein the generating polynomial of the PRBS signal generation circuit 13 is set to |1+x²+x³| is explained as an example, but this embodiment is not limited to this case.

### Second Embodiment

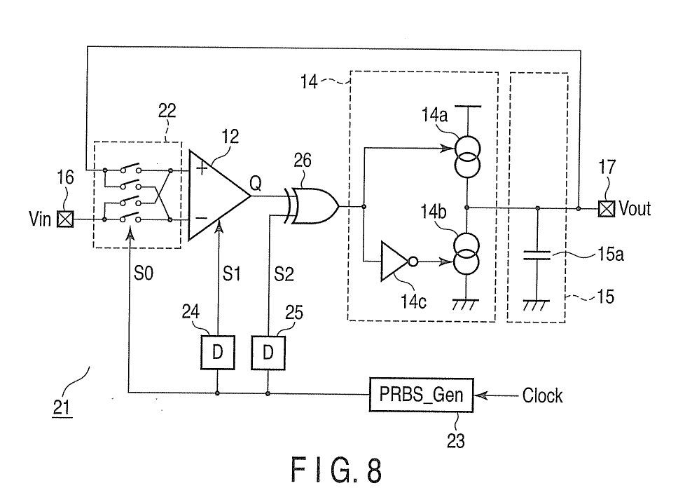

FIG. 8 shows an example of the configuration of an amplifier circuit according to a second embodiment. Also, in this embodiment, an amplifier circuit applying a random sampling system is taken as an example and explained. This embodiment is an example in which the amplifier circuit is a random sampling amplifier circuit suitably in the input stage of a digital-analog converter (DAC), for example, that is mounted in an LSI. The DAC is a circuit that is severe with respect to a modulation frequency component and input offset. Further, portions which are the same as those of the first embodiment are denoted by the same reference symbols and the detailed explanation thereof is omitted.

As shown in FIG. 8, the amplifier circuit 21 includes a cross switch 22, clocked comparator (switching amplifier) 12, PRBS signal generation circuit (PRBS_Gen) 23, delay circuits (D) 24, 25, EX-OR circuit 26, charge pump 14 and low-pass filter (LPF) 15.

An input terminal 16 of signal (for example, an infinitesimal signal of DC to several MHz) Vin or an output terminal of the low-pass filter 15 is connected to an inverting input terminal (−) of the clocked comparator 12 via the cross switch 22.

Further, the output terminal of the low-pass filter 15 or the input terminal 16 of signal Vin is connected to a non-inverting input terminal (+) of the clocked comparator 12 via the cross switch 22.

The clocked comparator 12 compares signals Vin and Vout at the timing of a rising edge or falling edge of signal S1.

Further, an output terminal 17 of signal Vout is connected to the output terminal of the low-pass filter 15.

The cross switch 22 is controlled by a PRBS signal (S0) from the PRBS signal generation circuit 23. That is, the cross switch 22 interchanges inputs (signals Vin, Vout) of the clocked comparator 12 based on the PRBS signal. In other words, signals Vin, Vout sampled based on the PRBS signal are alternately input to the inverting input terminal (−) and non-inverting input terminal (+) of the clocked comparator 12. As a result, signals Vin, Vout input to the clocked comparator 12 may be averaged and input offset may be canceled.

The PRBS signal generation circuit 23 generates a pseudo random period pattern signal whose clock period irregularly varies according to a generating polynomial |1+x⁶+x⁷| as a PRBS signal.

The delay circuit 24 delays a PRBS signal received from the PRBS signal generation circuit 23 according to the operation of the amplifier circuit 21 and outputs the delayed signal as delay signal S1. Delay signal S1 is a signal which controls the generation timing of output Q of the clocked comparator 12. The delay circuit 24 includes two inverters (not shown), for example.

The delay circuit 25 delays a PRBS signal received from the PRBS signal generation circuit 13 according to the operation of the amplifier circuit 21 and outputs the delayed signal as delay signal S2. Delay signal S2 is input to one input terminal of the EX-OR circuit 26. The delay circuit 25 includes four inverters (not shown), for example.

The relationship of S1<S2 is set between the delay times by signals S1, S2. That is, the time required for delaying a PRBS signal until the PRBS signal is output as delay signal 52 after the PRBS signal is received from the PRBS signal generation circuit 13 is longer than the time required for delaying the PRBS signal until the PRBS signal is output as delay signal S1.

Further, since no delay circuit is used for signal S0, the relationship of S0<S1<S2 is set.

The EX-OR circuit 26 controls the charge pump 14 according to delay output S2 and output Q supplied to the other input terminal thereof. The EX-OR circuit 26 controls the charge pump 14 according to delay output S2.

That is, the EX-OR circuit 26 inverts the logical level (polarity) of output Q in connection with a control operation of the cross switch 22.

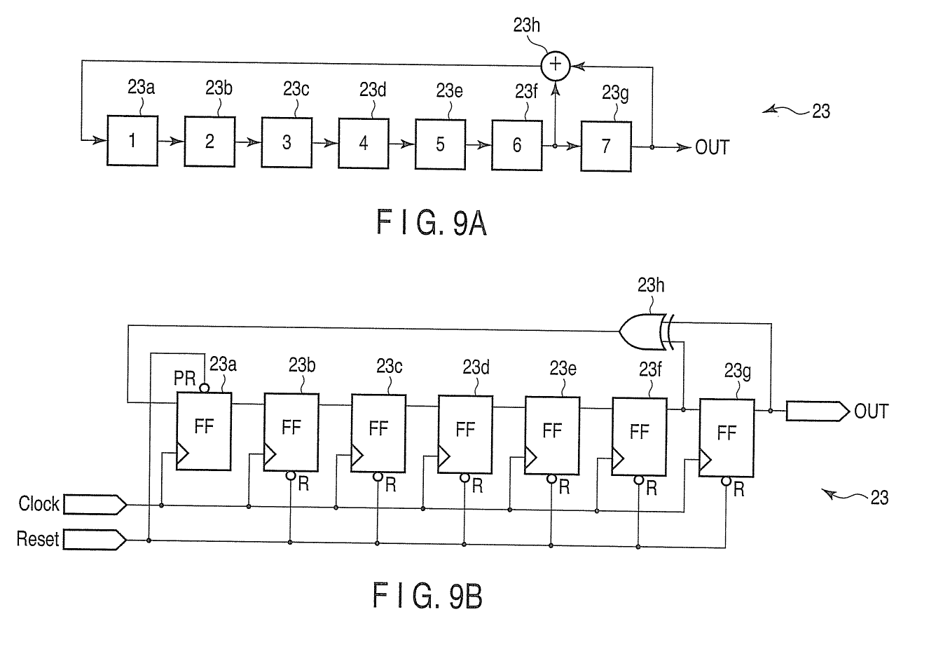

FIG. 9A, and FIG. 9B show an example of the configuration of the PRBS signal generation circuit 23. FIG. 9A is a block diagram when the generating polynomial is set to |1+x⁶+x⁷|. FIG. 9B is a circuit diagram concretely showing the configuration to realize the generating polynomial |1+x⁶+x⁷|.

For example, if the generating polynomial is set to |1+x⁶+x⁷|, the PRBS signal generation circuit 23 includes series-connected seven-stage flip-flop circuits (logical circuits) 23a, 23b, 23c, 23d, 23e, 23f and 23g and EX-OR circuit (addition circuit) 23h.

The EX-OR circuit (addition circuit) 23h performs an operation for an output of the sixth-stage flip-flop circuit 23f and an output (OUT) of the seventh-stage flip-flop circuit 23g and feeds back the operation result to the input of the first-stage flip-flop circuit 23a. Then, output OUT of the seventh-stage flip-flop circuit 23g is derived as a PRBS signal.

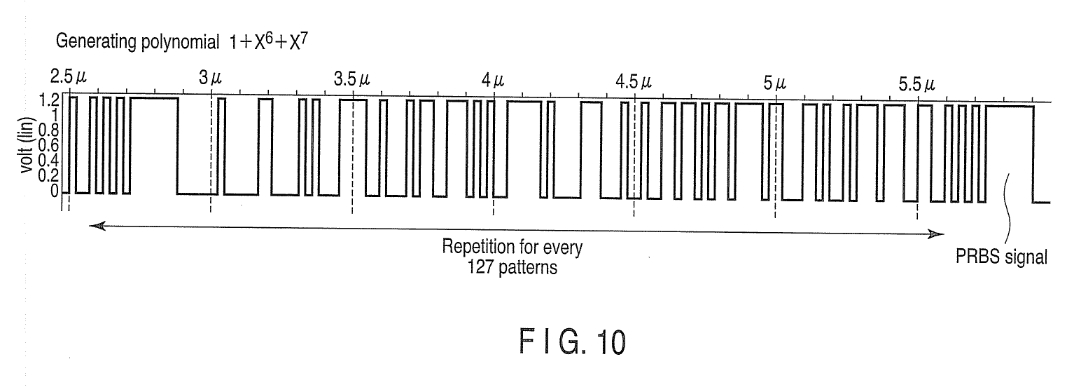

FIG. 10 shows an example of a PRBS signal generated by the PRBS signal generation circuit 23 with the configuration shown in FIG. 9.

As shown in FIG. 10, a PRBS signal of a pseudo random period pattern signal whose clock period irregularly varies according to the generating polynomial |1+x⁶+x⁷| is generated. Then, the PRBS signal is a signal such as white noise including no so-called specified frequency component.

In the PRBS signal, since a signal series of a certain pattern is repeated periodically (in the case of this example, for every 127 patterns), the modulation frequency components of a sampling clock may be dispersed.

Therefore, even if an LPF applying a large-capacitance capacitor is not used as the low-pass filter 15, the modulation frequency (high-frequency noise) components are easily removed.

This embodiment is similar to the first embodiment except which timing of input switching by the cross switch 22, timing of voltage comparison by the clocked comparator 12 and timing of logical inversion by the EX-OR circuit 26 are controlled and the generating polynomial of the PRBS signal generation circuit 23 is set to |1+x⁶+x⁷|.

Therefore, with the above configuration, like the case of the first embodiment, an amplifier circuit capable of amplifying an infinitesimal signal of DC to low frequency may be easily designed. This is because the comparator capable of sampling an input signal by using a PRBS signal is utilized.

Therefore, in comparison with the conventional amplifier circuit which uses a single clock as a sampling clock, the capacitance of a capacitor used in a circuit to reduce 1/f noise is reduced. Further, according to the configuration of this embodiment, the circuit design may be easily made, the circuit size may be reduced and the operation voltage may be lowered.

Further, with the configuration of this embodiment, not only 1/f noise but also input offset can be suppressed.

In the case of this embodiment, timing of input switching by the cross switch 22, timing of voltage comparison by the clocked comparator 12 and timing of logical inversion by the EX-OR circuit 26 become important. Therefore, it becomes necessary to generate proper timing signals (delay outputs S1, S2) by means of the delay circuits 24, 25.

In the second embodiment, a case wherein the generating polynomial of the PRBS signal generation circuit 23 is set to |1+x⁶+x⁷| is explained as an example, but this embodiment is not limited to this case.

Of course, the generating polynomial |1+x⁶+x⁷| explained in the second embodiment may be applied to the PRBS signal generation circuit 13 of the first embodiment shown in FIG. 1.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An amplifier circuit comprising:
a clock generation circuit which generates a pseudo random period pattern signal whose period varies,
a switching amplifier circuit which samples an input signal based on the pseudo random period pattern signal used as a sampling clock, and
a smoothing circuit which smoothes an output signal of the switching amplifier circuit.

2. The circuit according to claim 1, wherein the switching amplifier circuit is a clocked comparator.

3. The circuit according to claim 1, wherein the smoothing circuit includes
a low-pass filter including a capacitor and,
a charge pump which selectively charges and discharges the capacitor with a constant current according to an output of the switching amplifier circuit.

4. The circuit according to claim 1, wherein the pseudo random period pattern signal is a pseudo random bit sequence signal including no specified frequency component.

5. The circuit according to claim 1, further comprising a cross switch which switches input of the input signal input to the switching amplifier circuit.

6. The circuit according to claim 1, wherein the input signal includes
a first input signal to be amplified and a second input signal which is a reference signal of the first input signal output from the smoothing circuit,
the switching amplifier circuit outputs a result obtained by sampling the first input signal and the second input signal based on the pseudo random period pattern signal to the smoothing circuit.

7. The circuit according to claim 6, wherein the switching amplifier circuit outputs the result to the smoothing circuit at a rise time and fall time of the pseudo random period pattern signal.

8. The circuit according to claim 1, wherein the clock generation circuit includes
an ith flip-flop which generates an ith signal in synchronism with a clock signal,
an (i+1)th flip-flop which fetches the ith signal and generates an (i+1)th signal in synchronism with the clock signal,
a logical circuit which outputs an exclusive OR of the ith signal and the (i+1)th signal as an operation result, and
a flip-flop group which fetches the operation result and outputs the (i−1)th signal to the ith flip-flop in synchronism with the clock signal.

9. The circuit according to claim 1, wherein the clock generation circuit outputs the (i+1)th signal as the pseudo random period pattern signal.

10. An amplifier circuit comprising:
a clock generation circuit which generates a pseudo random period pattern signal whose period varies,
a comparator which compares a first input signal with a second input signal as a reference signal of the first input signal based on a pseudo random period pattern signal used as a sampling clock,
a charging portion which charges a potential of a first node according to a comparison result of the comparator,
a discharging portion which discharges the potential of the first node according to the comparison result of the comparator, and
a filter which passes a low-frequency component of the potential of the first node.

11. The circuit according to claim 10, wherein the comparator is a clocked comparator.

12. The circuit according to claim 11, wherein the pseudo random period pattern signal is a pseudo random bit sequence signal including no specified frequency component.

13. The circuit according to claim 11, wherein the clock generation circuit includes
an ith flip-flop which generates an ith signal in synchronism with a clock signal,
an (i+1)th flip-flop which fetches the ith signal and generates an (i+1)th signal in synchronism with the clock signal,
a logical circuit which outputs an exclusive OR of the ith signal and the (i+1)th signal as an operation result, and
a flip-flop group which fetches the operation result and outputs the (i−1)th signal to the ith flip-flop in synchronism with the clock signal.

14. The circuit according to claim 13, wherein the clock generation circuit outputs the (i+1)th signal as the pseudo random period pattern signal.

15. An amplifier circuit comprising:
a clock generation circuit which generates a pseudo random period pattern signal whose period varies,
a first delay circuit which delays the pseudo random period pattern signal as a sampling clock, the first delay circuit outputting the delayed pseudo random period pattern signal as a first signal,
a second delay circuit which delays the pseudo random period pattern signal, the second delay circuit outputting the delayed pseudo random period pattern signal as a second signal,
a switch which that selectively inverts and non-inverts a first input signal to be amplified and a second input signal as a reference signal of the first input signal based on the pseudo random period pattern signal,
a comparator which samples the first input signal and the second input signal based on the first signal,
a logical circuit which outputs an exclusive OR of a comparison result of the comparator and the second signal as a third signal, and
a smoothing circuit which smoothes the third signal and outputs the smoothed signal as the second input signal.

16. The circuit according to claim 15, wherein the comparator outputs the comparison result to the smoothing circuit at a rise time and fall time of the pseudo random period pattern signal.

17. The circuit according to claim 15, wherein the smoothing circuit includes
a low-pass filter including a capacitor and,
a charge pump which selectively charges and discharges the capacitor according to the comparison result of the comparator.

18. The circuit according to claim 15, wherein the comparator is a clocked comparator.

19. The circuit according to claim 18, wherein the pseudo random period pattern signal is a pseudo random bit sequence (PRBS) signal including no specified frequency component.

20. The circuit according to claim 15, wherein the clock generation circuit includes
an ith flip-flop which generates an ith signal in synchronism with a clock signal,
an (i+1)th flip-flop which fetches the ith signal and generates an (i+1)th signal in synchronism with the clock signal,
a logical circuit which outputs an exclusive OR of the ith signal and the (i+1)th signal as an operation result, and,
a flip-flop group which fetches the operation result and outputs the (i−1)th signal to the ith flip-flop in synchronism with the clock signal.
